(19) United States
(12) Patent Application Publication
(10) Pub. No.: US 2011/0037049 A1
(43) Pub. Date: Feb. 17, 2011

(54) NITRIDE SEMICONDUCTOR LIGHT-EMITTING DEVICE

(76) Inventors: Koichi TACHIBANA, Kawasaki-shi (JP); Hajime Nago, Yokohama-shi (JP); Toshiki Hikosaka, Fuchu-shi (JP); Shinya Nunoue, Ichikawa-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/717,653

(22) Filed: Mar. 4, 2010

Related U.S. Application Data
(63) Continuation of application No. PCT/JP09/64402, filed on Aug. 17, 2009.

(51) Int. Cl. H01L 33/04; H01L 33/30

(52) U.S. Cl. 257/13; 257/E33.008; 257/E33.026

(57) ABSTRACT

Disclosed is a nitride semiconductor light-emitting device including a substrate, a pair of p-type and n-type clad layers formed on the substrate, and an active layer having a single quantum well structure or a multiple quantum well structure, which is sandwiched between the p-type clad layer and the n-type clad layer, and includes a quantum well layer and a pair of barrier layers each having a larger bandgap than that of the quantum well layer, the quantum well layer being sandwiched between the pair of barrier layers. Each of the pair of barrier layers has a multi-layer structure including, starting from the quantum well layer side, a first subbarrier layer having a composition of In_{y1}Ga_{1-y1}N, a second subbarrier layer having a composition of In_{y2}Ga_{1-y2}N and a third subbarrier layer having a composition of In_{y3}Ga_{1-y3}N, in which y1, y2 and y3 satisfy the relationship of 0≦y1,y3<y2<1 and y1=y3.

### CROSS-REFERENCE TO RELATED APPLICATIONS

This is a Continuation Application of PCT Application No. PCT/JP2009/064402, filed Aug. 17, 2009, which was published under PCT Article 21(2) in Japanese.

### BACKGROUND OF THE INVENTION

1. Field of the Invention

This invention relates to a nitride semiconductor light-emitting device such as a light-emitting diode, a laser diode, etc.

2. Description of the Related Art

A nitride-based III-V compound semiconductor such as a gallium nitride (GaN) is known as a semiconductor having a wide bandgap. Because of this characteristics of the III-V compound semiconductor, high luminance light-emitting diodes (LED) emitting ultraviolet to blue-green light, or high luminance laser diodes (LD) emitting bluish violet to blue have been developed.

In order to enhance the quantum efficiency of the blue LED, it is important to enhance the crystallinity of GaN type semiconductor. Further, if it is desired to realize high optical outputs of the blue LED, it may be simply required to increase injecting current. However, it has been made clear through the investigation of the injecting current dependency of quantum efficiency that, although it is possible to realize high quantum efficiency in a low electric current region, the quantum efficiency is caused to decrease in a high electric current region. It has been, therefore, difficult to realize the LED exhibiting a high output and high quantum efficiency.

As a method of enhancing the crystallinity of GaN type semiconductor, there has been known a method of providing inclined profile of the In ratio in an InGaN quantum well layer (for example, JP-A 11-26812). Even with this method however, it has been found difficult to realize the blue LED exhibiting a high optical output and high quantum efficiency.

### BRIEF SUMMARY OF THE INVENTION

It is an object of the present invention to provide a nitride semiconductor light-emitting device which is capable of preventing the deterioration of quantum efficiency resulting from the injecting current dependency of quantum efficiency and exhibits a high optical output and quantum efficiency.

According to a first aspect of the present invention, there is provided a nitride semiconductor light-emitting device comprising: a substrate; a pair of p-type and n-type clad layers formed on the substrate, and an active layer having a single quantum well structure or a multiple quantum well structure, which is sandwiched between the p-type clad layer and the n-type clad layer, and includes a quantum well layer and a pair of barrier layers each having a larger bandgap than that of the quantum well layer, the quantum well layer being sandwiched between the pair of barrier layers, and each of the pair of barrier layers having a multi-layer structure including, starting from the quantum well layer side, a first subbarrier layer having a composition of In_{y1}Ga_{1-y1}N, a second subbarrier layer having a composition of In_{y2}Ga_{1-y2}N and a third subbarrier layer having a composition of In_{y3}Ga_{1-y3}N, in which y1, y2 and y3 satisfy the relationship of 0≦y1,y3<y2<1 and y1=y3.

According to a second aspect of the present invention, there is provided a nitride semiconductor light-emitting device comprising: a substrate; a pair of p-type and n-type clad layers formed on the substrate, and an active layer having a single quantum well structure or a multiple quantum well structure, which is sandwiched between the p-type clad layer and the n-type clad layer, and includes a quantum well layer and a pair of barrier layers each having a larger bandgap than that of the quantum well layer, the quantum well layer being sandwiched between the pair of barrier layers, and each of the pair of barrier layers having a multi-layer structure including, starting from the quantum well layer side, a first subbarrier layer having a composition of In_{y1}Ga_{1-y1-x}A1ₓ₁N, a second subbarrier layer having a composition of In_{y2}Ga_{1-y2-x2}A1ₓ₂N and a third subbarrier layer having a composition of In_{y3}Ga_{1-y3-x3}Alₓ₃N, in which y1, y2, y3, x1, x2 and x3 satisfy the relationship of 0≦y1,y3<y2<1, y1=y3 and 0≦x1,x2,x3<1.

### BRIEF DESCRIPTION OF THE SEVERAL VIEWS OF THE DRAWING

FIG. 1 is a cross-sectional view illustrating the construction of the semiconductor light-emitting devices according to Examples 1 and 2;

FIG. 2 is a diagram illustrating the bandgap of the semiconductor light-emitting devices according to Examples 1 and 2;

FIG. 3 is a graph illustrating the relationships between the quantum efficiency and the injecting current in the blue LEDs of Examples 1 and 2 and in a blue LED which was beyond the scope of the present invention;

FIG. 4 is a diagram illustrating the energy level of conduction band of the barrier layer A in the blue LEDs of Examples 1 and 2;

FIG. 5 is a diagram illustrating the energy level of conduction band of the barrier layer B in a two-layer structure;

FIG. 6 is a diagram illustrating the energy level of conduction band of the barrier layer C in a three-layer structure where the construction of width of bandgap was opposite to that of the present invention; and

FIG. 7 is a diagram illustrating the energy level of conduction band of the barrier layer D in a single-layer structure.

### DETAILED DESCRIPTION OF THE INVENTION

There will now be described various embodiments of the present invention.

The nitride light-emitting device according to one embodiment of the present invention has a double heterostructure wherein an active layer of quantum well structure is sandwiched between a pair of clad layers, i.e. a p-type clad layer and an n-type clad layer. In this case, the active layer of quantum well structure includes a quantum well layer and a pair of barrier layers both having a larger bandgap than that of the quantum well layer, the active layer being sandwiched between the pair of barrier layers. Each of the pair of barrier layers has a multi-layer structure including, starting from the quantum well layer side, a first subbarrier layer, a second subbarrier layer and a third subbarrier layer.

The quantum well layer is formed of InGaN for example, and the pair of barrier layers are respectively formed of a ternary nitride such as InGaN having a different composition from that of the quantum well layer or formed of a quaternary nitride such as InGaAlN. Incidentally, the n-type clad layer may be formed of an n-type GaN and the p-type clad layer may be formed of a p-type GaN.

In a case where the barrier layer is formed of a ternary nitride, the pair of barrier layers may respectively include, starting from the quantum well layer side, a first subbarrier layer having a composition of In_{y1}Ga_{1-y1}N, a second subbarrier layer having a composition of In_{y2}Ga_{1-y2}N and a third subbarrier layer having a composition of In_{y3}Ga_{1-y3}N, in which y1, y2 and y3 satisfy the relationship of 0≦y1,y3<y2<1 and y1=y3.

In a case where the barrier layer is formed of a quaternary nitride, the pair of barrier layers may respectively include, starting from the quantum well layer side, a first subbarrier layer having a composition of In_{y1}Ga_{1-y1-x1}Alₓ₁N, a second subbarrier layer having a composition of In_{y2}Ga_{1-y2-x2}Alₓ₂N and a third subbarrier layer having a composition of In_{y3}Ga_{1-y3-x3}Alₓ₃N, in which y1, y2, y3, x1, x2 and x3 satisfy the relationship of 0≦y1, y3<y2<1, y1=y3 and 0≦x1, x2, x3<1.

By making use of the barrier layer having a layer structure of the aforementioned composition, it is possible to reduce the internal electric field to be applied to the active layer. As a result, it is possible to obtain a nitride semiconductor light-emitting device exhibiting a high optical output and a high quantum efficiency.

In the nitride semiconductor light-emitting device according to the first embodiment of the present invention, when the film thickness of the barrier layer is defined as being b nm, the film thickness of each of the first and third subbarrier layer may be confined to the range of not less than 0.25 nm and less than (b/2) nm. When the barrier layer has a layer structure of such a film thickness, it is possible to obtain the effects that the quantum efficiency becomes excellent even the injecting current density is high. If the film thickness of each of the first and third subbarrier layer is less than 0.25 nm, it would lead to the generation of defects at the interface between the subbarrier layers and the quantum well, resulting in the deterioration of quantum efficiency. If the film thickness of each of the first and third subbarrier layer is larger than (b/2) nm, strain may be excessively imposed to the active layer as a whole, thus contrarily inviting the deterioration of quantum efficiency.

Further, the film thickness of each of the first and third subbarrier layer may be made smaller than the film thickness of the second subbarrier layer. By doing so, it is possible to obtain the effects that the quantum efficiency becomes more excellent even the injecting current density is high. When the film thickness of each of the first and third subbarrier layer is made equal to or more than the film thickness of the second subbarrier layer, the deterioration of quantum efficiency may be caused to occur.

Further, the barrier layer may be doped with an n-type impurity. By doing so, it is possible to obtain the effects that the quantum efficiency can be entirely enhanced. The quantity of doping may preferably be confined to 1×10¹⁷ to 1×10¹⁹ cm⁻³ or so.

Incidentally, in order to enhance the emission efficiency, the quantum well layer may preferably be left undoped.

Next, specific examples of the present invention will be explained as follows.

### Example 1

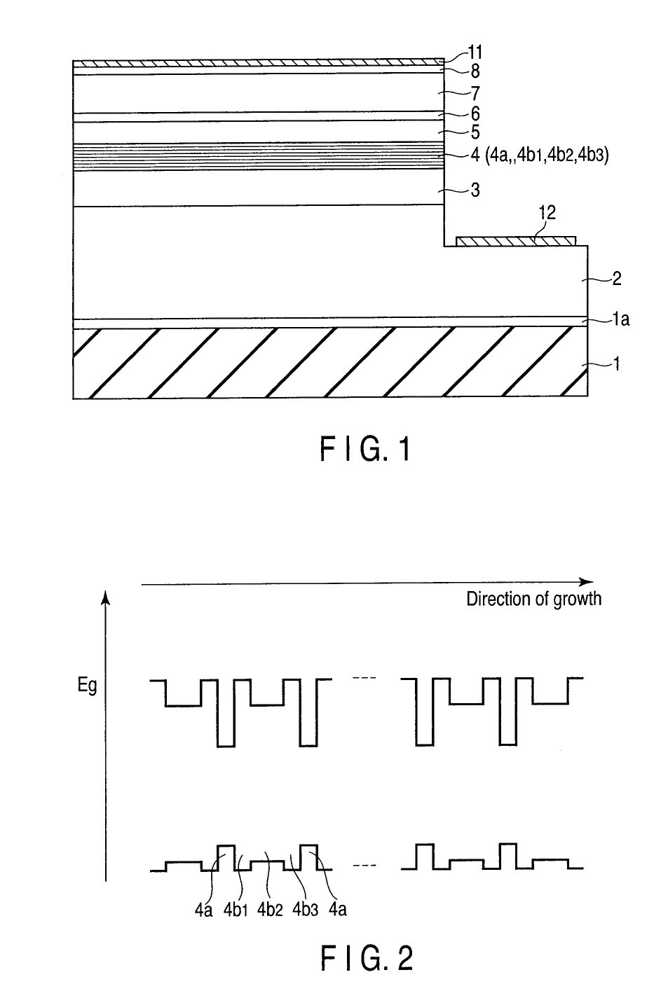

FIG. 1 shows a cross-sectional structure of the nitride semiconductor light-emitting diode according to Examples 1 of the present invention. The light-emitting diode shown in FIG. 1 has a structure including an n-type GaN layer 2, an n-type GaN guide layer 3, an active layer 4, a p-type GaN first guide layer 5, a p-type GaAlN layer (an electron overflow-preventing layer 6), a p-type GaN second guide layer 7, and a p-type GaN contact layer 8, which are successively laminated on the surface of a sapphire substrate 1. Further, an n-electrode 12 is formed on the surface of the n-type GaN layer 2, and a p-electrode 11 is formed on the surface of the p-type GaN contact layer 8. Namely, this light-emitting diode has a double heterostructure wherein the active layer 4 is sandwiched between the n-type GaN guide layer 3 functioning as an n-type clad layer and the p-type GaN first guide layer 5 functioning as a p-type clad layer.

The light-emitting diode shown in FIG. 1 can be manufactured as follows.

First of all, a buffer layer la having a composition of Ga₁₋ₐAlₐN (0≦a≦1) and a film thickness of about 20 nm is formed on the surface of the sapphire substrate 1. Then, the n-type GaN layer 2 doped with an n-type impurity and having a thickness of about 5000 nm is grown, by the crystal growth method, on the surface of the buffer layer 1a. This crystal growth can be executed by making use of, for example, metal organic chemical vapor deposition (MOCVD). Instead of the MOCVD, this crystal growth may be executed by making use of molecular beam epitaxy (MBE). Each of the following layers may be also formed according to any of the aforementioned methods.

As for the n-type impurity, although it is possible to employ various elements such as Si, Ge, Sn, etc., Si is selected in this example. With respect to the quantity of doping of Si, it may be 2×10¹⁸ cm⁻³ or so.

Although sapphire is employed herein as the substrate 1, the material for the substrate 1 may not be limited to sapphire, but various materials such as GaN, SiC, Si, GaAs, etc. may be employed.

Next, the n-type guide layer 3 constituted by GaN doped with an n-type impurity, e.g. Si, at a dosage of 1×10¹⁸ cm⁻³ or so and having a film thickness of about 0.1 pm is grown, by the crystal growth method, on the surface of the n-type GaN layer 2. The temperature to be employed on the occasion of growing any of the n-type GaN layer 2 and the n-type guide layer 3 may be 1000° C. to 1100° C. Further, the n-type guide layer may not be limited to the GaN layer but may be formed of an In_{0.01}Ga_{0.99}N layer having a film thickness of about 0.1 μm. The temperature to be employed on the occasion of growing the In_{0.01}Ga_{0.99}N layer may be 700° C. to 800° C.

Then, the active layer 4 having a multiple quantum well (MQW) structure is formed on the surface of the n-type guide layer 3. In this case, the multiple quantum well structure include a quantum well layer 4a formed of undoped In_{0.2}Ga_{0.8}N and having a film thickness of about 2.5 nm and barrier layers 4b (4b₁, 4b₂, 4b₃) each formed of In_{y}Ga_{1-y}N and having a film thickness of about 12.5 nm. The quantum well layer 4a and barrier layers 4b (4b₁, 4b₂, 4b₃) are alternately laminated in such a manner that the quantum well layer 4a is sandwiched between groups of these barrier layers 4b. The temperature to be employed on growing the active layer 4 may be 700° C. to 800° C. Incidentally, in this example, the wavelength of photoluminescence at room temperature was designed so as to have 450 nm.

As shown in FIG. 2 for example, the barrier layer 4b has a laminate structure including a first subbarrier layer 4b₁ (In_{0.02}Ga_{0.98}N layer) having an In ratio of 0.02 and a film thickness of 2 nm and being in contact with the left side quantum well layer 4a; a second subbarrier layer 4b₂ (In_{0.05}Ga_{0.95}N layer) having an In ratio of 0.05, a film thickness of 8.5 nm and being not in contact with the quantum well layer 4a; and a third subbarrier layer 4b₃ (In_{0.02}Ga_{0.98}N layer) having an In ratio of 0.02 and a film thickness of 2 nm and being in contact with the right side quantum well layer 4a. All of the first, second and third subbarrier layers 4b₁, 4b₂, 4b₃ may be doped with Si, i.e. an n-type impurity at a dosage of 1×10¹⁸ cm⁻³ or so, or may not be doped with the n-type impurity. On the other hand, in order to enhance the emission efficiency, the quantum well layer 4a may preferably be left undoped.

Then, the p-type first guide layer 5 having a composition of GaN is grown on the surface of active layer 4. The film thickness of the p-type first guide layer 5 may be about 30 nm. The temperature for growing the GaN may be 1000° C. to 1100° C. As for the p-type impurity, although it is possible to employ various elements such as Mg, Zn, etc., Mg is selected in this example. With respect to the quantity of doping of Mg, it may be 4×10¹⁸ cm⁻³ or so. Further, with respect to the p-type first guide layer, it is possible to employ an In_{0.01}Ga_{0.99}N layer having a film thickness of about 30 nm. The temperature to be employed on the occasion of growing the In_{0.01}Ga_{0.99}N layer may be 700° C. to 800° C.

Then, a Ga_{0.8}Al_{0.2}N layer having a film thickness of about 10 nm and doped with Mg as a p-type impurity is grown as an electron overflow-preventing layer 6 on the surface of the p-type first guide layer 5. With respect to the quantity of doping of Mg, it may be 4×10¹⁸ cm⁻³ or so. The temperature for growing the Ga_{0.8}Al_{0.2}N layer may be 1000° C. to 1100° C.

Then, a p-type GaN second guide layer 7 doped with Mg at a dosage of 1×10¹⁹ cm⁻³ or so is grown on the surface of the electron overflow-preventing layer 6. With respect to the film thickness of the second guide layer 7, it may be 50 nm or so. The temperature for growing the GaN may be 1000° C. to 1100° C.

Finally, a p-type GaN contact layer 8 doped with Mg at a dosage of 1×10²⁰ cm⁻³ or so and having a film thickness of about 60 nm is grown on the surface of p-type GaN second guide layer 7.

To the multilayer structure formed through aforementioned crystal growth, the following device-finishing processes are applied, thereby finally manufacturing the light-emitting diode.

Namely, a p-type electrode 11 formed, for example, of a composite film of palladium-platinum-gold (Pd/Pt/Au) is formed on the surface of the p-type GaN contact layer 8. For example, the Pd film may be 0.05 μm in thickness, the Pt film may be 0.05 μm in thickness, and the Au film may be 0.05 μm in thickness. Alternatively, the p-type electrode 11 may be a transparent electrode made of indium tin oxide (ITO) or a reflective electrode made of silver (Ag).

After forming the p-type electrode 11, dry etching is selectively applied to the resultant structure thus obtained, thereby enabling the n-type GaN layer 2 to partially expose. Then, an n-type electrode 12 is formed on this exposed portion of the n-type GaN layer 2. This n-type electrode 12 may be a composite film of titanium-platinum-gold (Ti/Pt/Au). This composite film may be constituted, for example, by a Ti film having a thickness of about 0.05 μm, a Pt film having a thickness of about 0.05 μm, and an Au film having a thickness of about 1.0 μm.

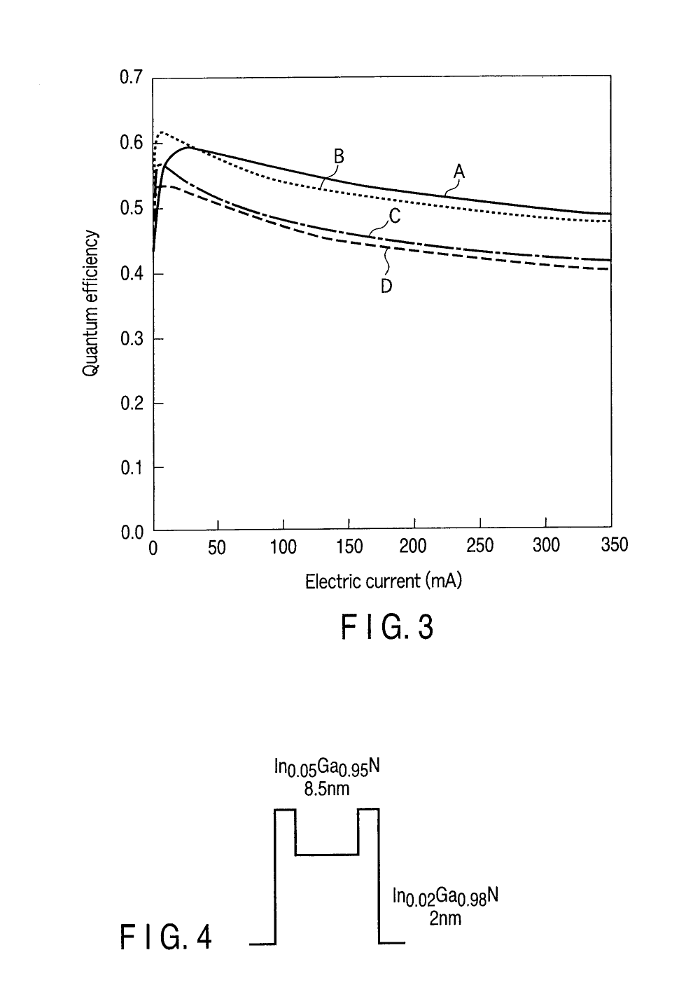

Then, tests for determining the relationship between the electric current and the quantum efficiency were performed on the blue LED manufactured as described above according to this example and on other three kinds of LEDs (the lamination of the barrier layers or the In ratio fails to satisfy the requirements of the present invention). The results obtained are shown in FIG. 3.

In FIG. 3, a curve “A” represents the relationship between the electric current and the quantum efficiency in the blue LED according to this example, which was provided with the barrier layer A including the first, the second and the third subbarriers as shown in above FIG. 2. A curve “B” represents the relationship between the electric current and the quantum efficiency in an LED having the same construction as the blue LED according to this example excepting that it was provided with a barrier layer B of two-layer structure including an In_{0.02}Ga_{0.98}N layer having a film thickness of 2 nm and an In_{0.05}Ga_{0.95}N layer having a film thickness of 10.5 nm. A curve “C” represents the relationship between the electric current and the quantum efficiency in an LED having the same construction as the blue LED according to this example excepting that it was provided with a barrier layer C of three-layer structure including an In_{0.05}Ga_{0.95}N layer having a film thickness of 2 nm, an In_{0.02}Ga_{0.98}N layer having a film thickness of 8.5 nm and an In_{0.05}Ga_{0.95}N layer having a film thickness of 2 nm. A curve “D” represents the relationship between the electric current and the quantum efficiency in an LED having the same construction as the blue LED according to this example excepting that it was provided with a barrier layer D of single-layer structure consisting of an In_{0.02}Ga_{0.98}N layer having a film thickness of 12.5 nm.

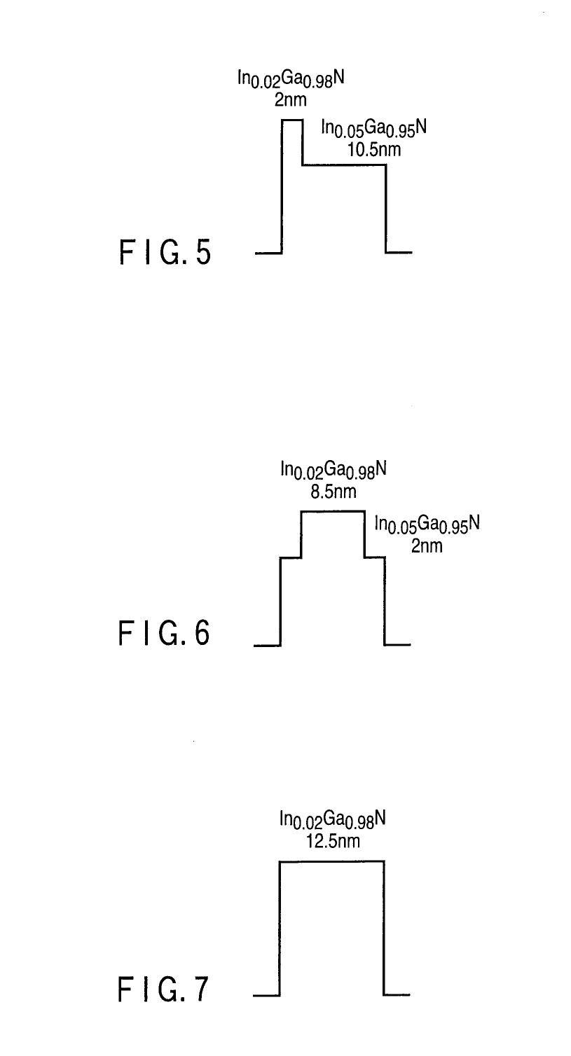

The energy levels of the conduction band of the barrier layers A, B, C and D are shown in FIGS. 4, 5, 6 and 7, respectively.

Following facts will be clearly recognized from FIG. 3. Namely, as shown by the curve “A”, in the case of the LED according to Example 1, even in a high electric current region of not less than 50 mA, the quantum efficiency was not lowered so much. The reason for this may be assumably attributed to the facts that since a three-layer structure constituted by a subbarrier layer having a relatively small In ratio (the first subbarrier layer 4b₁), a subbarrier layer having a relatively large In ratio (the second subbarrier layer 4b₂) and a subbarrier layer having a relatively small In ratio (the third subbarrier layer 4b₃) was employed as the barrier layer 4b, and, at the same time, a subbarrier layer having a relatively large In ratio (the first subbarrier layer 4b₁) was interposed between the quantum well layer 4a and the second subbarrier layer 4b₂, it was made possible to minimize the piezopolarization and hence to reduce the internal electric field to be imposed to the active layer.

Whereas, in the case of the LED where a barrier layer of a two-layer structure including a subbarrier layer having a relatively small In ratio and a subbarrier layer having a relatively large In ratio was employed, although the quantum efficiency was not lowered so much even in a high electric current region of not less than 50 mA as shown by the curve “B”, the quantum efficiency was lower than the LED of this embodiment.

In the case of the LED including a barrier layer of a three-layer structure in which a subbarrier layer having a relatively large In ratio, a subbarrier layer having a relatively small In ratio and a subbarrier layer having a relatively large In ratio were laminated in the mentioned order contrary to that of the present invention, was employed, it will be recognized that the quantum efficiency was prominently lowered in a high electric current region of not less than 50 mA as shown by the curve “C”. Further, in the case of the LED including a barrier layer of a single-layer structure was employed, the same trend as that of the curve “C” was indicated, but resulting in a further lowered quantum efficiency as shown by the curve “D”.

### Example 2

In the case of Example 1, a three-layer structure comprising a first subbarrier layer 4b₁ having a composition of In_{0.02}Ga_{0.98}N layer, a second subbarrier layer 4b₂ having a composition of In_{0.05}Ga_{0.95}N layer, and a third subbarrier layer 4b₃ having a composition of In_{0.02}Ga_{0.98}N layer was employed as the barrier layer 4b. All of these subbarrier layers are formed using a ternary system of In_{y}Ga_{1-y}N (0<y<l).

Whereas, in this Example 2, a three-layer structure including a first subbarrier layer 4b₁ having a composition of In_{0.02}Ga_{0.97}Al_{0.01}N layer, a second subbarrier layer 4b₂ having a composition of In_{0.05}Ga_{0.94}Al_{0.01}N layer, and a third subbarrier layer 4b₃ having a composition of In_{0.02}Ga_{0.97}Al_{0.01}N layer was employed as the barrier layer 4b. In any of these subbarrier layers, a quaternary system of In_{y}Ga_{1-y-x}AlₓN (0<x, y<1) was employed.

A blue LED was manufactured in the same manner as described in Example 1 except that a barrier layer 4b used herein had the aforementioned structure of a quaternary system of In_{y}Ga_{1-y-x}AlₓN. Then, tests for determining the relationship between the electric current and the quantum efficiency were performed on this blue LED. As a result, this blue LED was indicated almost the same excellent performances as those of the blue LED of Example 1 as indicated by the curve “A” of FIG. 3.

Incidentally, the present invention is not limited to the above-described embodiments and examples but constituent elements of these embodiments and examples may be variously modified in actual use thereof without departing from the spirit of the present invention. Further, the constituent elements described in these various embodiments and examples may be suitably combined to create various inventions. Further, the compositions and film thickness described in these various embodiments and examples represent simply some of examples and hence they may be variously selected.

What is claimed is:

1. A nitride semiconductor light-emitting device comprising:
a substrate;
a pair of p-type and n-type clad layers formed on a surface of the substrate, and
an active layer having a single quantum well structure or a multiple quantum well structure, which is sandwiched between the p-type clad layer and the n-type clad layer, and includes a quantum well layer and a pair of barrier layers each having a larger bandgap than that of the quantum well layer, said quantum well layer being sandwiched between the pair of barrier layers, and each of the pair of barrier layers having a multi-layer structure including, starting from the quantum well layer side, a first subbarrier layer having a composition of In_{y1}Ga_{1-y1}N, a second subbarrier layer having a composition of In_{y2}Ga_{1-y2}N and a third subbarrier layer having a composition of In_{y3}Ga_{1-y3}N, in which y1, y2 and y3 satisfy the relationship of 0≦y1,y3<y2<1 and y1=y3.

2. The device according to claim 1, wherein, when the film thickness of the barrier layer is defined as being b nm, the film thickness of each of the first and third subbarrier layer is confined to range from not less than 0.25 nm and less than (b/2) nm.

3. The device according to claim 1, wherein the first and third subbarrier layers respectively have a film thickness which is smaller than that of the second subbarrier layer.

4. The device according to claim 1, wherein the barrier layer is doped with an n-type impurity.

5. A nitride semiconductor light-emitting device comprising:
a substrate;
a pair of p-type and n-type clad layers formed on a surface of the substrate, and
an active layer having a single quantum well structure or a multiple quantum well structure, which is sandwiched between the p-type clad layer and the n-type clad layer, and includes a quantum well layer and a pair of barrier layers each having a larger bandgap than that of the quantum well layer, said quantum well layer being sandwiched between the pair of barrier layers, and each of the pair of barrier layers having a multi-layer structure including, starting from the quantum well layer side, a first subbarrier layer having a composition of In_{y1}Ga_{1-y1-x1}Alₓ₋₁N, a second subbarrier layer having a composition of In_{y2}Ga_{1-y2-x2}Alₓ₂N and a third subbarrier layer having a composition of In_{y3}Ga_{1-y3-x3}Alₓ₃N, in which y1, y2, y3, x1, x2 and x3 satisfy the relationship of 0≦y1,y3<y2<1, y1=y3 and 0≦x1,x2,x3<1.

6. The device according to claim 5, wherein, when the film thickness of the barrier layer is defined as being b nm, the film thickness of each of the first and third subbarrier layer is confined to range from not less than 0.25 nm and less than (b/2) nm.

7. The device according to claim 5, wherein the first and third subbarrier layers respectively have a film thickness which is smaller than that of the second subbarrier layer.

8. The device according to claim 5, wherein the barrier layer is doped with an n-type impurity.
